(19) United States
(12) Patent Application Publication
(10) Pub. No.: US 2026/0351306 A1
(43) Pub. Date: Nov. 5, 2026

(54) Power Multiplexer Circuitry and Methods

(71) Applicant: Arm Limited, Cambridge (GB)

(72) Inventors: Piyush Jain, Noida (IN); Parmanand Singh, Ghaziabad (IN); Utkarsh Singh, Noida (IN); Vineet Dimri, Noida (IN); Ashish Bhardwaj, Noida (IN)

(21) Appl. No.: 19/195,640

(22) Filed: Apr. 30, 2025

(51) Int. Cl. G11C 11/412; G11C 11/419; H10B 10/00

(52) U.S. Cl. CPC G11C 11/412; G11C 11/419; H10B 10/12

(57) ABSTRACT

A circuit for power multiplexing comprising: a bitcell array powered by a first internal supply mesh; wordline driver circuitry powered by a second internal supply mesh; and a coupling element coupling the first internal supply mesh with the second internal supply mesh, where the coupling element is configured to substantially match voltage transitions between the first internal supply mesh and the second internal supply mesh.

### FIELD

The present disclosure is generally related to systems, methods, and devices for power multiplexer circuitry.

### DESCRIPTION OF RELATED ART

Modern memory circuits often use integrated power multiplexers (PMUXes) that enable dynamic switching between two or more external voltage domains, such as a core voltage domain (VDDCE) and a peripheral voltage domain (VDDPE). These integrated power multiplexers selectively provide power to internal supply meshes associated with key memory circuitry components, including bitcell arrays and wordline driver circuitry. Typically, the internal bitcell array supply mesh (e.g., core mesh, VDDC) and the internal wordline driver supply mesh (e.g., VDDCX) should maintain synchronized voltage transitions when switching between external voltage domains. Maintaining synchronized and closely matched voltage transitions between these internal meshes is important because mismatches or voltage skews can adversely impact memory reliability, functionality, and performance. However, achieving synchronization is challenging due to significantly different loading conditions of the bitcell array mesh and the wordline driver mesh, resulting in differences in voltage ramp rates during switching events.

For example, when integrated PMUX circuitry switches from one external supply domain to another under certain conditions, such as power supply variation (e.g., PSV corners), the internal supply mesh for the bitcell array (VDDC) may exhibit a substantially slower ramp rate compared to the wordline driver supply mesh (VDDCX). Such ramp-rate mismatches cause transient voltage differences, increasing short-circuit currents, power consumption, and potential timing violations. Existing approaches to mitigate these mismatches have significant drawbacks. For instance, certain approaches to balance ramp rates results in undesirable area penalties, increased leakage current, and uneven scalability across memory instances. In addition, other existing methods fail to consistently achieve desired synchronization, further complicating timing verification and qualification processes across various memory sizes. Accordingly, there exists a pressing need for improved solutions to effectively synchronize internal mesh voltage transitions during dynamic voltage domain switching, without significantly increasing layout complexity, leakage currents, or compromising memory performance.

### BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2 is a diagram of an example circuit in accordance with various implementations described herein.

FIG. 3 is a diagram of an example circuit in accordance with various implementations described herein.

FIG. 4 is a diagram of an example circuit in accordance with various implementations described herein.

FIG. 5 is an operational method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

Implementations of the present disclosure are described below with reference to the drawings. In the description, common features are designated by common reference numbers throughout the drawings.

In one implementation, the present disclosure describes a circuit for power multiplexing including: a bitcell array powered by a first internal supply mesh; wordline driver circuitry powered by a second internal supply mesh; and a coupling element coupling the first internal supply mesh with the second internal supply mesh. Also, the coupling element is configured to substantially match voltage transitions between the first internal supply mesh and the second internal supply mesh.

In another implementation, the present disclosure describes a circuit for power multiplexing including: a bitcell array powered by a first internal supply mesh; wordline driver circuitry powered by a second internal supply mesh; a pair of power headers configured to selectively couple the first internal supply mesh to external voltage domains; and a wordline driver header transistor coupled between the first internal supply mesh and the second internal supply mesh. Also, the wordline driver header transistor is configured to power the second internal supply mesh from the first internal supply mesh.

In another implementation, the present disclosure describes a circuit for power multiplexing including: a bitcell array powered by a first internal supply mesh; wordline driver circuitry powered by a second internal supply mesh; and an equalizer circuit coupling the first and second internal supply meshes. Also, the equalizer circuit is configured to actively equalize voltage transitions between the first and second internal supply meshes during switching between external voltage domains.

Inventive aspects address the above challenges by introducing novel power gating schemes and techniques for memories that incorporate integrated power multiplexing (IPMUX). While certain implementations focus on SRAM, the disclosed innovations apply broadly to any memory architecture employing IPMUX functionality, including dual-port, multi-port, and dedicated read/write architectures (e.g., 8T bitcell memories).

Central to these inventive aspects is a unifying structural concept: strategically establishing intentional coupling between two internal power supply meshes (VDDC and VDDCX) that were conventionally isolated from one another. More specifically, inventive implementations described herein achieve synchronization between these internal meshes by:
Selectively coupling wordline driver headers at their inputs to external voltage domains (e.g., peripheral domain VDDPE and/or core domain VDDCE);
Similarly coupling bitcell array headers at their inputs to external voltage domains; and
Internally coupling outputs of these headers, thereby connecting the previously separate wordline driver supply mesh (VDDCX) and bitcell array supply mesh (VDDC).

By providing this intentional electrical coupling between the internal supply meshes, the inventive aspects dramatically reduce transient voltage skews and ensure synchronous voltage ramping during IPMUX switching events. Various exemplary embodiments illustrate this central inventive concept, including coupling via headers (Follow Core Supply (FCS) implementation), direct conductive coupling (Direct Short implementation), and active circuit-based coupling (Equalizer implementation). Each of these schemes strategically establishes electrical coupling to synchronize voltage transitions, representing a significant departure from traditional approaches in which internal supply meshes remain independently powered and isolated.

This unified approach of intentional mesh coupling substantially enhances memory robustness during dynamic voltage switching events, reduces transient currents, and improves reliability; where such advantages are particularly beneficial for Dynamic Voltage Frequency Scaling (DVFS) environments. As a result, memory instances incorporating the inventive IPMUX coupling schemes and techniques achieve superior operational reliability, improved performance consistency, and enhanced power-management flexibility.

Certain definitions have been provided herein for reference. A power multiplexer (PMUX) refers to a circuit arrangement configured to selectively couple an internal power supply mesh to one of two or more external voltage supply domains. A PMUX typically includes transistor devices—such as PMOS transistors—configured to selectively switch between external voltage domains based on received control signals, thereby providing dynamic selection and switching of supply voltages to a particular internal power mesh.

Power multiplexer headers (e.g., “PMUX headers” or “power headers”) refer to transistor devices, typically including pairs of PMOS transistors, configured to selectively couple an internal supply mesh to one of two or more external voltage domains based on received control signals. Each transistor of the pair is coupled to a respective external voltage domain.

As used herein, the term “memory macro” refers to an integrated memory circuit block comprising multiple functional sections. These sections typically include a bitcell array, wordline driver circuitry, column multiplexing circuitry, local input/output (IO) circuitry, central timing or clocking circuitry, control logic, and dedicated internal supply meshes (e.g., VDDC and VDDCX). Memory macros may be implemented in various layout arrangements, such as the butterfly architecture characterized by centrally located wordline drivers and peripheral IO circuitry. Such layouts facilitate balanced loading, optimized power distribution, and improved memory performance. Accordingly, a memory macro represents a self-contained memory unit suitable for integration within larger semiconductor devices, system-on-chip (SoC) architectures, processors, and other integrated circuit designs. The term “bitcell array” refers broadly to a structured arrangement of memory cells configured to store data bits. Example bitcell array architectures include static random-access memory (SRAM), dual-port memory arrays, multi-port memory arrays, and memory arrays having dedicated read and write ports, such as 8T bitcell configurations. Bitcell arrays typically include multiple rows and columns of bitcells.

The term “internal supply mesh” refers to an internal power-distribution network within a memory circuit. Internal supply meshes are formed from conductive metal layers, routing lines, or conductive paths arranged to distribute power internally to specific circuit blocks, such as a bitcell array or wordline driver circuitry, within a memory macro or integrated circuit. The term “external voltage domains” refers to externally supplied voltage sources provided to an integrated circuit or memory macro, each potentially having distinct voltage levels or characteristics. Examples of external voltage domains include peripheral voltage domains (VDDPE) and core voltage domains (VDDCE). As used herein, the term “coupling element” broadly encompasses conductive elements, transistor devices, or active circuits configured to interconnect or electrically couple two or more internal supply meshes or nodes. Coupling elements may include direct conductive paths, transistor devices (e.g., PMOS or NMOS transistors), active equalization circuits, or combinations thereof, configured to facilitate synchronization or equalization of voltage levels or transitions between internal supply meshes.

“Synchronizing” (or substantially “matching”) voltage transitions refers to controlling voltage transitions or ramp rates of two or more internal supply meshes, ensuring minimal transient voltage differences between those meshes during voltage domain switching or other dynamic supply-voltage events. A conductive path or direct connection refers to an intentional low-resistance electrical connection (e.g., a metal or conductive line) provided between internal supply meshes, allowing simultaneous voltage transitions with minimal or negligible voltage offset.

An equalizer circuit is a circuit component or transistor configured to actively equalize, balance, or match voltage levels between two internal supply meshes during voltage transitions. Typically implemented as an active transistor device (e.g., such as a PMOS transistor), the equalizer is controlled by an equalizer control signal. An equalizer control signal is a control input (e.g., “Eq_in”) to an equalizer transistor device. The equalizer control signal determines whether the equalizer transistor is activated or deactivated based on operational modes or states, such as a chip enable (CEN), quick-nap (Qnap), or retention (RET) signal. Operational modes refer to different modes or states of operation of the memory device or circuit. Exemplary operational modes include: 1) active operation mode (mission mode): Read/write mode in which the memory actively performs data operations; 2) standby mode: Lower-power operational mode where active data operations may be halted; and 3) retention mode: A low-power operational mode where data is preserved but read/write operations are inactive.

A wordline driver header transistor refers to a transistor (typically PMOS) placed between a first internal supply mesh (e.g., core mesh) and a second internal supply mesh (e.g., wordline driver mesh). In some implementations (FCS embodiment), the wordline driver header transistor directly powers the second internal mesh (wordline driver mesh) from the first internal supply mesh (core mesh), enabling the second mesh to closely track voltage transitions of the first internal supply mesh. The term “track” refers to the behavior of one internal supply mesh closely following or mirroring the voltage transitions of another internal supply mesh, where voltage transitions of one mesh occur substantially simultaneously with or within a minimal transient voltage difference (e.g., less than approximately 10-15 millivolts) relative to the other mesh during voltage domain switching events.

The signals SEL_VL and NSEL_VL refer respectively to a voltage-level selection signal and its complementary (inverted) counterpart, used within integrated power multiplexer (PMUX) circuits to selectively enable switching between external voltage domains. The signal PDW refers to a power-down control signal used to enable or initiate low-power operational modes, such as retention or standby modes. The signal nhdr_wl refers to an active-low wordline header enable signal configured to selectively activate or deactivate wordline driver header transistors, thereby controlling coupling between internal supply meshes (e.g., VDDC and

### Vddcx) Within Memory Macros.

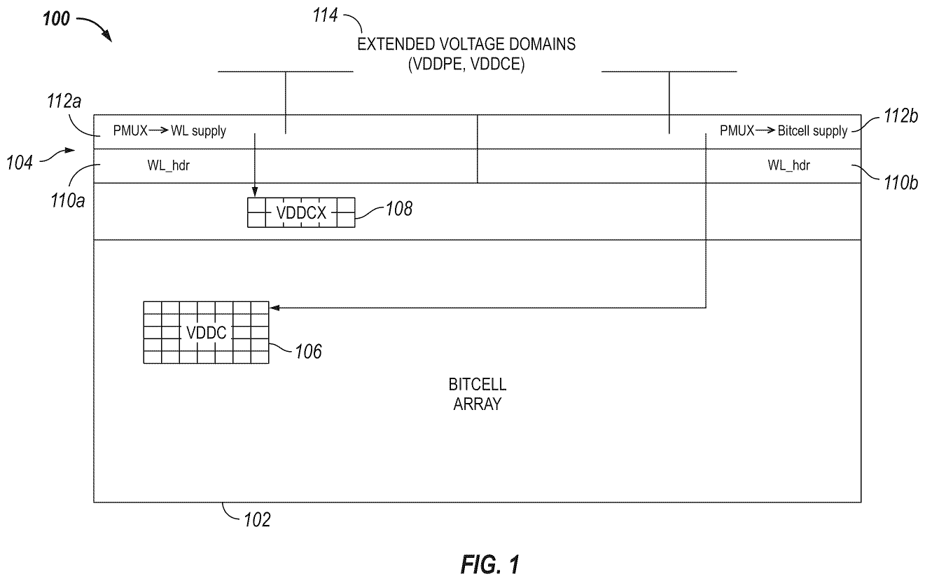

Referring to FIG. 1, a simplified plan view layout of a portion of a Static Random-Access Memory (SRAM) macro is shown according to example implementations. The SRAM macro 100 generally includes a bitcell array 102 (e.g., one or more bitcell arrays) and associated wordline driver circuitry 104 arranged adjacent or in proximity to the bitcell array 102. In certain aspects, the bitcell array 102 is powered by a dedicated internal power supply mesh 106 (i.e., bitcell mesh) (e.g., “VDDC”), and the wordline driver circuitry 104 is powered by a separate internal supply mesh 108 (i.e., wordline driver mesh) (e.g., “VDDCX”). For example, the internal power supply meshes 106, 108 can be conductive grids, metal layers, or routing lines configured to distribute supply voltages within their respective circuit regions. In some implementations, as shown, respective internal power supply meshes 106, 108 may be located within the bitcell array 102 and wordline driver circuitry 104. In other implementations, the respective internal power supply meshes 106, 108 may be located outside of or adjacent to the bitcell array and wordline driver circuitry in other locations, for example, of the SRAM macro 100.

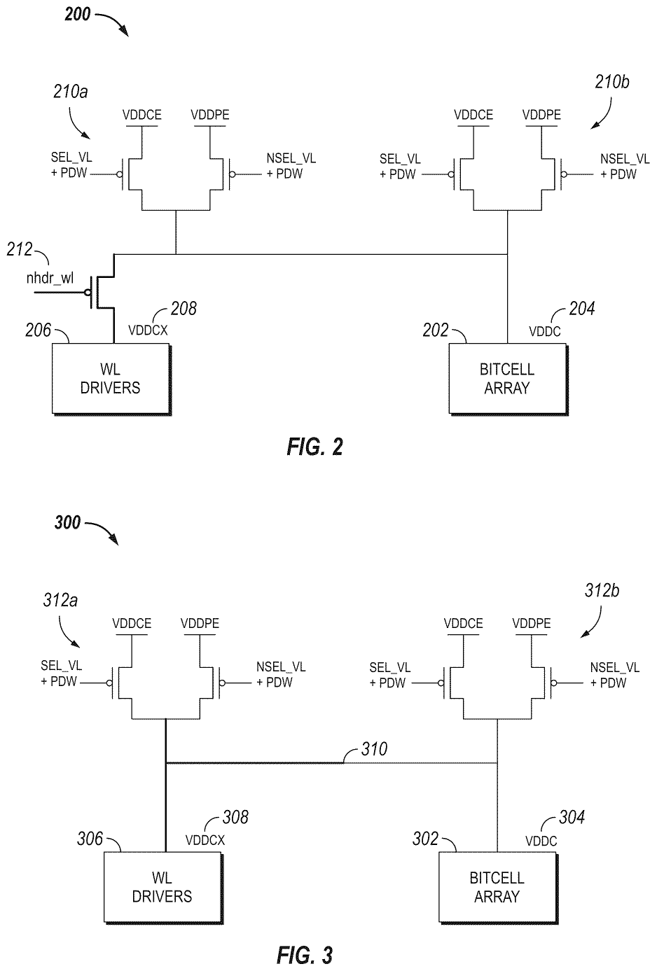

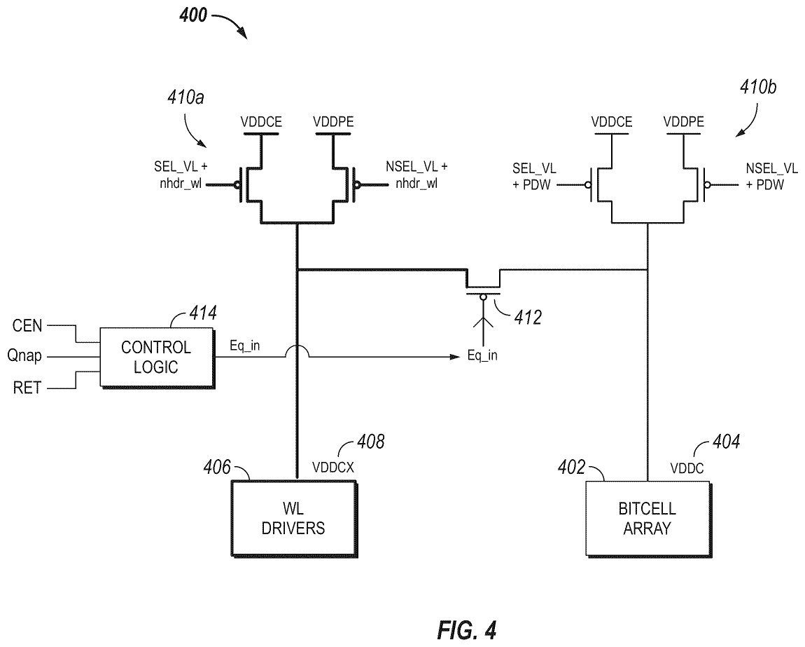

As shown, the wordline driver circuitry 104 includes respective wordline driver headers 110a, 110b (“WL_hdr”) that provide power to the wordline driver mesh 108 (VDDCX) and to the bitcell mesh 106. For instance, the WL headers 110a, 110b are coupled to external voltage domains (e.g., peripheral supply voltage “VDDPE” or core supply voltage “VDDCE”) via power multiplexer (PMUX) circuitry 112 (e.g., first and second PMUX circuitry 112a, 112b) (e.g., “PMUX→WL supply”). In various cases, the PMUX circuitry 112 allows dynamic selection of external voltage domains, enabling power optimization and flexibility during memory operation. Advantageously, implementations described herein introduce novel coupling arrangements to reduce these transient voltage skews between meshes 106 (VDDC) and 108 (VDDCX). Such coupling arrangements, which will be illustrated in further detail in subsequent figures (e.g., FIG. 2, FIG. 3, FIG. 4, etc.), include direct conductive coupling (shorting), indirect coupling via headers (e.g., Follow Core Supply (FCS) configuration), and active transistor-based equalizer circuits. These inventive coupling schemes significantly reduce transient voltage differences between the internal supply meshes 106 and 108, thereby improving operational robustness and enabling flexible dynamic voltage scaling. It should be appreciated that FIG. 1 is provided as a simplified conceptual layout, and that actual implementations may include additional structures, elements, or routing layers to achieve the described inventive functionality.

Referring to FIG. 2, a schematic diagram of an exemplary memory circuit 200 is shown according to example implementations. For instance, the circuit 200 is configured to reduce transient voltage skews arising during dynamic power multiplexing switching events. In certain aspects, the circuit 200 includes a bitcell array 202 powered by a first internal supply mesh 204 (VDDC), and wordline (WL) driver circuitry 206 powered by a second internal supply mesh 208 (VDDCX). The circuit 200 further includes power multiplexer (PMUX) headers implemented as transistor pairs 210 (210a, 210b) (e.g., pairs of PMOS transistors). The PMUX headers 210 selectively couple the first internal supply mesh 204 to one of multiple external voltage domains, such as a peripheral external supply voltage (VDDPE) or a core external supply voltage (VDDCE”), based on control signals (e.g., SEL_VL+PDW, NSEL_VL+PDW).

In the illustrated implementation, the second internal supply mesh 208 (VDDCX) powering the WL driver circuitry 206 receives its supply indirectly from the first internal supply mesh 204 (VDDC) via a wordline driver header 212 (e.g., a coupling element; a PMOS transistor having a gate terminal controlled by a header enable signal “nhdr_wl”). Thus, rather than directly coupling to external supply domains (e.g., peripheral voltage VDDPE or core voltage VDDCE), the WL driver header 212 is directly coupled between the first internal supply mesh 204 and the second internal supply mesh 208, powering the WL driver circuitry 206 from the bitcell array supply mesh 204.

This hierarchical powering arrangement advantageously causes voltage transitions of the second internal supply mesh 208 (VDDCX) to closely track (e.g. follow) those of the first internal supply mesh 204 (VDDC). Consequently, whenever the integrated PMUX headers 210 dynamically switch between external voltage domains (e.g., VDDPE and VDDCE), transient voltage skew between the two internal supply meshes 204, 208 is substantially minimized. In addition, simulations, further demonstrate that this “Follow Core Supply” (FCS) arrangement reduces transient voltage skew from approximately 65-75 millivolts (in known architectures) down to approximately 9-10 millivolts.

Advantageously, this substantial reduction in transient skew significantly improves memory robustness, reducing the likelihood of bit errors and enhancing active data maintenance (ADM), read, and write margin stability. Moreover, the arrangement maintains scalability across memory instances of various sizes and layouts, ensuring robust voltage synchronization without significant performance penalties or loss of power-saving flexibility.

Referring to FIG. 3, a schematic diagram of a memory circuit 300 is shown according to example implementations. As illustrated, the circuit 300 is configured to directly short internal supply meshes so as to reduce transient voltage skews during dynamic power multiplexing switching events. In certain aspects, the circuit 300 includes a bitcell array 302 powered by a first internal supply mesh 304 (VDDC), and wordline (WL) driver circuitry 306 powered by a second internal supply mesh 308 (VDDCX). In such aspects, the first internal supply mesh 304 (VDDC) and the second internal supply mesh 308 (VDDCX) are directly coupled via a conductive path 310 (e.g., a coupling element; a conductive metal path). Specifically, for example, the conductive path 310 is routed directly between the meshes 304 and 308, effectively shorting them together. Thus, the meshes 304, 308 inherently transition simultaneously during power multiplexing switching events.

In addition, power multiplexer (PMUX) headers, implemented as pairs of PMOS transistors, 312 (e.g., 312a, 312b), selectively couple the shorted internal meshes 304, 308 to external voltage domains, such as peripheral external supply voltage (VDDPE) or core external supply voltage (VDDCE), based on respective control signals (SEL_VL+PDW, NSEL_VL+PDW). Due to the direct conductive coupling 310, both internal meshes 304, 308 rise and fall synchronously, significantly reducing transient voltage skew during external supply transitions. Simulations of this direct coupling configuration demonstrate substantial reductions in transient voltage skew—from approximately 65-75 millivolts in conventional systems down to approximately 11-12 millivolts. This dramatic reduction greatly improves memory reliability and robustness, particularly with respect to active data maintenance (ADM), read margin, and write margin. Advantageously, the direct coupling solution is straightforward and highly reliable, and is particularly beneficial for memory applications prioritizing robustness over independent power control flexibility.

Referring to FIG. 4, a schematic diagram of a memory circuit 400 is shown according to example implementations. As illustrated, the circuit 400 is configured to dynamically balance voltage transitions between internal supply meshes during dynamic power multiplexing switching events. In certain aspects, the circuit 400 includes a bitcell array 402 powered by a first internal supply mesh 404 (VDDC), and wordline (WL) driver circuitry 406 powered by a second internal supply mesh 408 (VDDCX). Also, power multiplexer (PMUX) headers 410 (e.g., 410a, 410b), implemented as pairs of PMOS transistors, selectively couple each internal supply mesh 404, 408 to external voltage domains, such as peripheral external supply voltage (VDDPE) or core external supply voltage (VDDCE), based on control signals (SEL_VL+PDW, NSEL_VL+PDW).

In certain aspects, the circuit 400 further includes an equalizer circuit 412 (e.g., a coupling element) positioned between and coupling the first internal supply mesh 404 with the second internal supply mesh 408. As one example, the equalizer circuit 412 includes at least one PMOS transistor, having a source terminal coupled to the first internal supply mesh 404 (VDDC), a drain terminal coupled to the second internal supply mesh 408 (VDDCX), and a gate terminal configured to receive an equalizer control signal (“Eq_in”).

In various cases, control logic 414 selectively generates the equalizer control signal (“Eq_in”) based on one or more operational control signals, such as a chip enable signal (CEN), quick-nap signal (Qnap), or retention signal (RET). Specifically, the control logic 414 activates (e.g., “turns ON”) the equalizer transistor 412 during active operational modes (e.g., mission mode, read/write mode) and deactivates (e.g., “turns OFF”) the equalizer circuit 412 during low-power operational modes, such as standby or retention modes. In certain examples, the equalizer transistor 412 is activated when the CEN signal indicates active mode and deactivated when the RET signal indicates retention mode or when the CEN signal indicates standby mode.

When active, the equalizer circuit 412 dynamically balances (e.g., actively equalizes) the voltage transitions between the first internal supply mesh 404 and the second internal supply mesh 408 during power-multiplexing switching events. As a result, transient voltage skew between the internal meshes is significantly reduced—from approximately 65-75 millivolts observed in conventional systems down to approximately 24-25 millivolts—thereby substantially improving memory robustness, including active data maintenance (ADM), read margin, and write margin. Advantageously, such an equalizer arrangement preserves independent power control flexibility, enabling the wordline driver circuitry 406 to independently enter low-power standby or retention modes, while simultaneously ensuring robust voltage synchronization during normal active operation. As a further advantage, the circuit 400 is applicable broadly to various types of memory architectures, including Static Random-Access Memory (SRAM) arrays, multi-port memory arrays, and dedicated-port memory bitcell configurations.

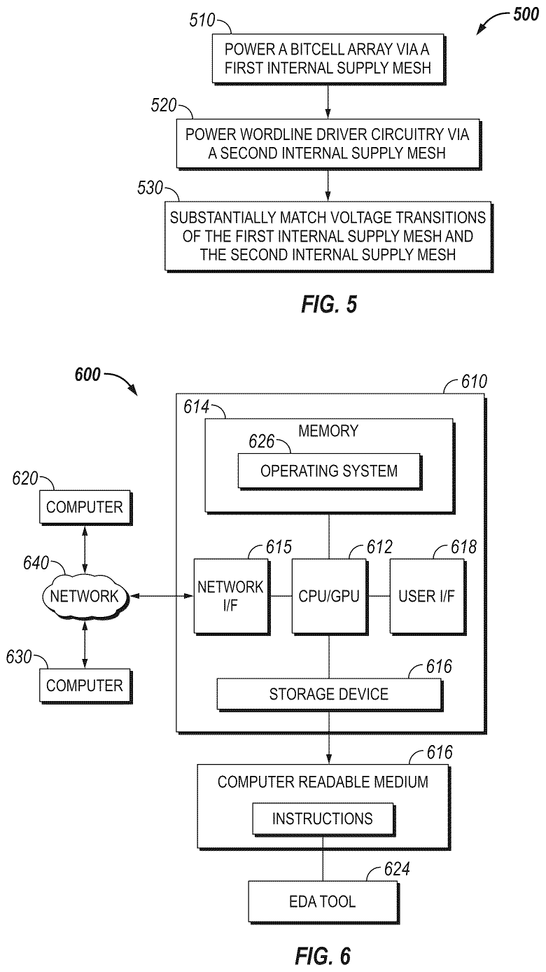

Referring to FIG. 5, a flowchart 500 depicting an exemplary method of power multiplexing in memory circuitry is shown according to example implementations. The method 500 may be performed by circuits or systems such as those described above with respect to FIGS. 2-4, and specifically relates to dynamically matching voltage transitions of internal supply meshes to improve memory operational robustness.

The method 500 begins at step 510 by powering a bitcell array via a first internal supply mesh, for example, a VDDC mesh as described above in FIG. 2-4. At step 520, the method includes separately powering associated wordline driver circuitry via a second internal supply mesh, for example, a VDDCX mesh as described above in FIGS. 2-4.

Next, at step 530, the method substantially matches (e.g., synchronizes) voltage transitions of the first internal supply mesh and the second internal supply mesh. As discussed in the examples of FIG. 2-4, substantially matching voltage transitions may involve actively coordinating, equalizing, or coupling the internal supply meshes to significantly reduce transient voltage skew during dynamic switching between external supply domains.

In certain implementations, substantially matching voltage transitions in step 530 includes powering the second internal supply mesh directly from the first internal supply mesh via a wordline driver header transistor, as explicitly described above with respect to FIG. 2 in the Follow Core Supply (FCS) implementation. According to this FCS implementation, the voltage transitions of the second internal supply mesh VDDCX track or closely follow those of the first internal supply mesh VDDC, typically within a predetermined voltage difference of less than approximately 15 millivolts, thereby significantly improving memory reliability and robustness.

In further implementations, substantially matching voltage transitions in step 530 includes directly coupling the first and second internal supply meshes via a conductive path (e.g., direct short), as described explicitly above with respect to FIG. 3. Specifically, in these implementations, a conductive path directly connects the internal meshes VDDC and VDDCX, ensuring inherent synchronous ramping of both internal meshes during power multiplexing events, thereby substantially reducing transient voltage skew.

In yet other implementations, substantially matching voltage transitions in step 530 includes actively equalizing (e.g., dynamically balancing) the respective voltages of the internal supply meshes via an equalizer circuit, as described explicitly above with respect to FIG. 4. In such cases, the method 500 further includes selectively activating and deactivating the equalizer circuit based on operational modes of the memory circuit. Specifically, the equalizer circuit is enabled during active read or write operations (mission mode) to actively equalize voltages, and disabled during at least one of standby mode or retention mode to optimize power savings.

In some aspects, the method 500 further includes dynamically switching the first and second internal supply meshes between external voltage domains, such as peripheral voltage domain VDDPE and core voltage domain VDDCE, to accommodate different operational and power-saving modes. Accordingly, the method 500 thus advantageously enhances robustness and performance of memory circuits employing dynamic power multiplexing (IPMUX) functionality by effectively minimizing transient voltage skew, thereby improving active data maintenance (ADM), read margin, and write margin performance.

FIG. 6 illustrates example hardware components in a computer system 600 that may be utilized to facilitate the design, verification, simulation, and optimization of the inventive memory architecture and associated power multiplexing circuitry disclosed herein. In certain implementations, the example computer system 600, which may represent a networked computer system or server, includes at least one electronic design automation (EDA) tool 624 configured to execute software procedures described herein with reference to FIGS. 1-5. For instance, the EDA tool 624 automates the design, analysis, and implementation of power multiplexing techniques and internal mesh coupling schemes, such as those previously described with reference to circuits 200, 300, 400 and methods described by flowchart 500.

In certain implementations, the EDA tool 624 may be included as a component of existing electronic design compiler software. The EDA tool 624 specifically automates the synthesis, simulation, and verification of the power multiplexing circuitry as disclosed herein. For example, the tool automates generation and verification of coupling schemes (e.g., Follow Core Supply (FCS), direct short, and equalizer implementations) between internal supply meshes to minimize transient voltage skew during dynamic switching between external supply domains (VDDPE, VDDCE). In various implementations, the EDA tool 624 generates custom transistor-level circuits or netlists implementing the inventive coupling configurations. For example, the tool may synthesize transistor-level netlists for coupling elements, such as conductive paths (FIG. 3, conductive path 310), equalizer transistor circuits (FIG. 4, equalizer transistor 412), and header transistor arrangements (FIG. 2, wordline driver header transistor 212). Functional and transient simulations performed by the EDA tool 624 validate synchronization effectiveness and memory robustness by measuring voltage skew reductions, confirming that internal meshes (e.g., VDDC and VDDCX) match voltage transitions within predetermined target margins (e.g., 10-15 millivolts).

Additionally, the EDA tool 624 performs critical timing analyses and dynamic switching evaluations, optimizing the size and placement of headers, equalizer transistors, and associated control logic (such as logic 414 in FIG. 4), to ensure robust and timely synchronization of internal mesh voltages. Physical design steps performed by the EDA tool 624 optimize transistor placement and routing to reduce leakage, minimize area penalties, and enhance circuit performance. The tool 624 further performs formal verification and generates test vectors to ensure design correctness and operational reliability in silicon implementations.

In certain aspects, procedures (e.g., method 500 of FIG. 5), as described herein, may be stored as program instructions 617 in a computer-readable medium, such as a storage device 616 or memory 614. These instructions 617 may be executed by one or more computers or servers 610, 620, 630. In some cases, each of these computing systems 610, 620, 630 may comprise any type of computer, workstation, server, or programmable electronic device. Further, each computing system 610, 620, 630 may operate individually or within a distributed computing system connected via a network 640. The computer 610 generally includes a central processing unit (CPU) 612 (or in some cases, a graphics processing unit (GPU), neural processing unit (NPU), or other specialized processor) having at least one hardware-based processor coupled to memory 614. Memory 614 may represent random access memory (RAM), cache memory, non-volatile memory (e.g., flash memory), read-only memory (ROM), or combinations thereof. Additional memory or storage may also be present elsewhere within the computer system 600, such as supplemental cache memory within the CPU 612 or virtual memory stored on the storage device 616 or in another computing device connected via the network 640.

For instance, the computer 610 may further include a user interface (I/F) 618, allowing interaction with circuit designers or other operators. Interface 618 typically comprises user input devices such as keyboards, mice, touchpads, microphones, and display devices such as monitors or LCD/LED screens. The computer 610 also includes a network interface (I/F) 615 coupled to one or more networks 640 (wired or wireless), enabling communication and data exchange with remote computing devices or servers 620, 630. The computer 610 operates under control of an operating system 626, which may be stored in memory 614 or on storage device 616. Example operating systems include UNIX®, Linux®, Windows®, and others familiar to those skilled in the art. Software components, such as EDA tool 624 and instructions 617 for the inventive power multiplexing methods, may execute on CPU 612 or on multiple CPUs across networked computing devices 620, 630. The database of the computer system 600 may include data structures comprising cell libraries, technology files, design format files, Open Artwork System Interchange Standard (OASIS/OASIS.MASK) files, EDIF files, or other formats stored on memory 614, storage device 616, or across networked computers 620, 630. In certain implementations, system 600 supports semiconductor integrated circuit (IC) designs comprising standard cells, IP blocks, transistor-level custom designs, or combinations thereof. EDA tool 624 leverages database resources and standardized formats to generate optimized transistor-level netlists and layouts that incorporate the inventive internal mesh coupling and synchronization schemes, ensuring improved memory performance, power efficiency, and robustness in silicon implementations.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as Graphics Database System II (GDSII). The one or more netlists or other computer-readable representation of integrated circuit components may be generated by applying one or more logic synthesis processes to an RTL representation to generate definitions for use in fabrication of an apparatus embodying the invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for power multiplexing comprising:
a bitcell array powered by a first internal supply mesh;
wordline driver circuitry powered by a second internal supply mesh; and
a coupling element coupling the first internal supply mesh with the second internal supply mesh, wherein:
the coupling element is configured to substantially match voltage transitions between the first internal supply mesh and the second internal supply mesh.

2. The circuit of claim 1, wherein the coupling element is configured to synchronize voltage transitions during switching between first and second external voltage domains.

3. The circuit of claim 1, wherein the coupling element comprises a conductive path directly connecting the first internal supply mesh with the second internal supply mesh.

4. The circuit of claim 1, wherein the coupling element comprises an equalizer circuit configured to actively equalize voltage transitions between the first internal supply mesh and second internal supply mesh.

5. The circuit of claim 4, further comprising control logic configured to selectively activate and deactivate the equalizer circuit based on operational modes, wherein:
the control logic generates an equalizer control signal based on one or more of a chip enable (CEN) signal, a quick-nap (Qnap) signal, or a retention (RET) signal; and
the operational modes comprise an active operation mode and at least one of a standby mode or a retention mode.

6. The circuit of claim 5, wherein the control logic is configured to:
activate the equalizer circuit by asserting the equalizer control signal when the chip enable (CEN) signal indicates the active operation mode; and
deactivate the equalizer circuit when the retention (RET) signal indicates retention mode or when the chip enable (CEN) signal indicates the standby mode.

7. The circuit of claim 1, wherein the bitcell array comprises one of a Static Random-Access Memory (SRAM) array, multi-port, or dedicated-port memory bitcells.

8. The circuit of claim 1, wherein the coupling element comprises a wordline driver header coupled between the first internal supply mesh and the second internal supply mesh.

9. The circuit of claim 8, wherein the second internal supply mesh is powered from the first internal supply mesh through the wordline driver header.

10. The circuit of claim 9, further comprising:
a pair of power multiplexer headers configured to selectively couple the first internal supply mesh to external voltage domains.

11. The circuit of claim 10, wherein the wordline driver header comprises: a PMOS transistor having a gate configured to receive a control signal to selectively couple the second internal supply mesh to the first internal supply mesh.

12. A circuit for power multiplexing comprising:
a bitcell array powered by a first internal supply mesh;
wordline driver circuitry powered by a second internal supply mesh;
a pair of power headers configured to selectively couple the first internal supply mesh to external voltage domains; and
a wordline driver header transistor coupled between the first internal supply mesh and the second internal supply mesh, wherein:
the wordline driver header transistor is configured to power the second internal supply mesh from the first internal supply mesh.

13. The circuit of claim 12, wherein the second internal supply mesh tracks voltage transitions of the first internal supply mesh.

14. The circuit of claim 12, wherein the second internal supply mesh is powered from the first internal supply mesh through the wordline driver header.

15. The circuit of claim 12, wherein the wordline driver header comprises: a PMOS transistor having a gate configured to receive a control signal to selectively couple the second internal supply mesh to the first internal supply mesh.

16. A circuit for power multiplexing comprising:
a bitcell array powered by a first internal supply mesh;
wordline driver circuitry powered by a second internal supply mesh; and
an equalizer circuit coupling the first and second internal supply meshes, wherein the equalizer circuit is configured to actively equalize voltage transitions between the first and second internal supply meshes during switching between external voltage domains.

17. The circuit of claim 16, wherein the equalizer circuit comprises a PMOS transistor coupled between the first internal supply mesh and the second internal supply mesh.

18. The circuit of claim 16, further comprising:
control logic configured to generate an equalizer control signal to selectively activate or deactivate the equalizer circuit, wherein:
the control logic generates the equalizer control signal from one or more of a chip enable (CEN) signal, quick-nap (Qnap) signal, or retention (RET) signal.

19. The circuit of claim 16, wherein the bitcell array comprises a Static Random-Access Memory (SRAM) array.

20. The circuit of claim 17, wherein the bitcell array comprises at least one of dual-port, multi-port, or dedicated-port memory bitcells.
